(19) United States
(12) Patent Application Publication
(10) Pub. No.: US 2006/0141775 A1
(43) Pub. Date: Jun. 29, 2006

(54) Method of forming electrical connections in a semiconductor structure

(76) Inventors: Holger Schuehrer, Dresden (DE); Matthias Schaller, Dresden (DE); Christin Bartsch, Stolpen OT Lauterbach (DE)

Correspondence Address: WILLIAMS, MORGAN & AMERSON, 10333 RICHMOND, SUITE 1100, HOUSTON, TX, 77042, US

(21) Appl. No.: 11/196,883

(22) Filed: Aug. 4, 2005

(30) Foreign Application Priority Data
Dec. 29, 2004 (DE) 10 2004 063 264.2

(51) Int. Cl. H01L 21/4763; H01L 21/302

(52) U.S. Cl. 438/638; 438/734

(57) ABSTRACT

A method of forming a semiconductor structure comprises providing a substrate comprising a layer of a material formed on a first surface of the substrate. At least one recess is formed in the layer of material. The formation of the at least one recess comprises performing a dry etching process. A contamination layer formed in the dry etching process is removed from a second surface of the substrate. Thus, contaminations of tools used in later stages of the manufacturing process resulting from flakes splitting off the contamination layer may be avoided.

### BACKGROUND OF THE INVENTION

1. Field of the Invention

The present invention relates to the formation of integrated circuits, and, more particularly, to damascene processes for the formation of electrical connections between elements of an integrated circuit.

2. Description of the Related Art

Integrated circuits comprise a large number of individual circuit elements such as, e.g., transistors, capacitors and resistors, formed on a substrate. These elements are connected internally by means of electrically conductive lines to form complex circuits such as memory devices, logic devices and microprocessors.

The performance of integrated circuits can be improved by increasing the number of functional elements per circuit in order to increase their functionality and/or by increasing the speed of operation of the circuit elements. A reduction of feature sizes allows the formation of a greater number of circuit elements on the same area, hence allowing an extension of the functionality of the circuit, and also allows improvement of the switching speed of transistor elements. In modern integrated circuits, design rules of 90 nm or smaller can be applied.

As feature sizes are reduced, the floor space available for the electrically conductive lines is also reduced. Additionally, if the number of circuit elements is increased, a greater number of lines is required to connect the circuit elements. Hence, in order to accommodate the lines in the integrated circuit, the dimensions of the lines and the distances between the lines have to be reduced.

In modern integrated circuits, the metal lines are frequently formed by means of a so-called damascene process. In a damascene process, an interlayer dielectric stack is deposited on a semiconductor substrate. In the interlayer dielectric stack, contact vias and trenches are formed. The contact vias and trenches are then filled with an electrically conductive material, for example, a metal such as copper, to provide electrical contact between the circuit elements.

A damascene process according to the state of the art will now be described in more detail with reference to FIG. 1a. A semiconductor structure 100 comprises a substrate 101. The substrate 101 comprises at least one electrical element 106 which may be, e.g., an electrically conductive line. On a first surface 111 of the substrate 101, an interlayer dielectric stack 113 is formed. The interlayer dielectric stack comprises a first etch stop layer 102, a first layer 103 of an interlayer dielectric, a second etch stop layer 104, and a second layer 105 of an interlayer dielectric. The first etch stop layer 102, the first layer 103 of inter-layer dielectric, the second etch stop layer 104 and the second layer 105 of interlayer dielectric may be deposited successively by means of methods known to persons skilled in the art, including plasma enhanced chemical vapor deposition, chemical vapor deposition and/or spin coating.

Then, at least one contact via 107 is formed in the interlayer dielectric stack 113. To this end, a first mask (not shown) is formed on the semiconductor structure 100. The first mask may comprise a photoresist and exposes the interlayer dielectric stack 113 at those locations where the at least one contact via 107 is to be formed. As is well known to persons skilled in the art, a mask comprising a photoresist can be formed by applying the photoresist to the semiconductor structure 100, exposing the photoresist through a reticle and solving either the portions irradiated in the exposure or the non-irradiated portions in a developer.

A dry etching process is then performed. In the dry etching process, the semiconductor structure 100 is exposed to reactive species created in a plasma generated by a glow discharge in an etch gas. A bias voltage applied to an electrode located in the vicinity of the semiconductor structure 100 accelerates ions in the plasma towards the first surface 111 of the substrate 101. Frequently, the semiconductor structure 100 is cooled during the dry etching process.

Portions of the interlayer dielectric stack 113 covered by the first mask (not shown) are protected from being affected by the reactive species, whereas the exposed portion of the interlayer dielectric stack 113 is etched. In the etching process, portions of the second layer 105 of interlayer dielectric, the second etch stop layer 104 and the first layer 103 of interlayer dielectric are removed. The first etch stop layer 102 may protect the underlying circuit element 106 from being affected by the etchant and/or may provide an indication when the etch front has passed the layers provided over the first etch stop layer 102.

The motion of the ions towards the first surface 111 of the substrate 101 creates an anisotropy of the etching process. In anisotropic etching, an etch rate of substantially horizontal portions of the etched surface, measured in a direction substantially perpendicular to the surface, is significantly greater than an etch rate of inclined portions of the etched surface. Hence, no significant etching of portions of the interlayer dielectric stack 113 below the first mask occurs, and the contact via 107 obtains sidewalls substantially perpendicular to the surface of the interlayer dielectric stack 113.

Subsequently, the first mask is removed, and a trench 108 is formed in the semiconductor structure 100. The trench 108 may be formed by depositing a second mask (not shown) comprising a photoresist on the semiconductor structure 100. The second mask exposes those portions of the second layer of interlayer dielectric 105 wherein the trench 108 is to be formed, protecting the rest of the second layer of interlayer dielectric 105 from being affected by an etchant used in an anisotropic etching process subsequently performed. Residues of photoresist previously applied or any other material also remain inside the contact via 107 and protect portions of the semiconductor structure 100 below the contact via from being etched.

In the second etching process, portions of the second layer 105 of interlayer dielectric are removed. The second etch stop layer 104 may protect the first layer 103 of interlayer dielectric from being affected by the etchant and/or may provide an indication when the portion of the second interlayer dielectric 105 which is not covered by the second mask is removed. Due to the anisotropy of the etching process, the trench 108 obtains sidewalls being substantially perpendicular to the surface of the interlayer dielectric stack 113. After the anisotropic etching, the second mask is removed.

Then, a diffusion barrier layer 114 is deposited over the semiconductor structure 100. This may be done by means of known methods including plasma enhanced chemical vapor deposition, chemical vapor deposition or sputter deposition. Subsequently, a metal layer is formed over the semiconductor structure 100, for example, by means of electroplating which is well known to persons skilled in the art. The metal layer may comprise copper, for example. The metal layer fills the contact via 107 and the trench 108. Finally, a chemical mechanical polishing process is performed in order to remove portions of the metal layer outside the via 107 and the trench 108. Thus, an electrical connection 109 is formed.

A problem of the damascene process according to the state of the art is that, in stages of the manufacturing process performed after the dry etching processes performed in the formation of contact vias and trenches, contamination of the semiconductor structure 100 and/or tools used in the manufacturing process may occur. Such contamination may adversely affect a product yield of the process.

Therefore, there is a need for a damascene process allowing a reduction of contaminations and an improved product yield.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

According to one illustrative embodiment of the present invention, a method of forming a semiconductor structure comprises providing a substrate comprised of a layer of a material formed on a first surface of the substrate. At least one recess is formed in the layer of material by performing a dry etching process. A contamination layer formed in the dry etching process is removed from a second surface of the substrate.

According to another illustrative embodiment of the present invention, a method of forming a semiconductor structure comprises providing a substrate comprised of a layer of an interlayer dielectric formed over a front side of the substrate. At least one recess is formed in the layer of interlayer dielectric by performing a dry etching process. A polymer layer formed in the dry etching process is removed from a backside of the substrate.

### BRIEF DESCRIPTION OF THE DRAWINGS

The invention may be understood by reference to the following description taken in conjunction with the accompanying drawings, in which like reference numerals identify like elements, and in which:

FIG. 1a shows a schematic cross-sectional view of a semiconductor structure according to the state of the art;

FIGS. 1b and 1c show views of the semiconductor structure shown in FIG. 1a in stages of a manufacturing process according to the state of the art; and

FIGS. 2a-2c show schematic cross-sectional views of a semiconductor structure in stages of a manufacturing process according to the present invention.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Various structures, systems and devices are schematically depicted in the drawings for purposes of explanation only and so as to not obscure the present invention with details that are well known to those skilled in the art. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present invention is based on the realization that contamination which occurs in the damascene process according to the state of the art may be caused by the presence of a contamination layer which is formed on a second surface of a substrate in a dry etching process applied to form at least one recess in a layer of material located on a first surface of the substrate.

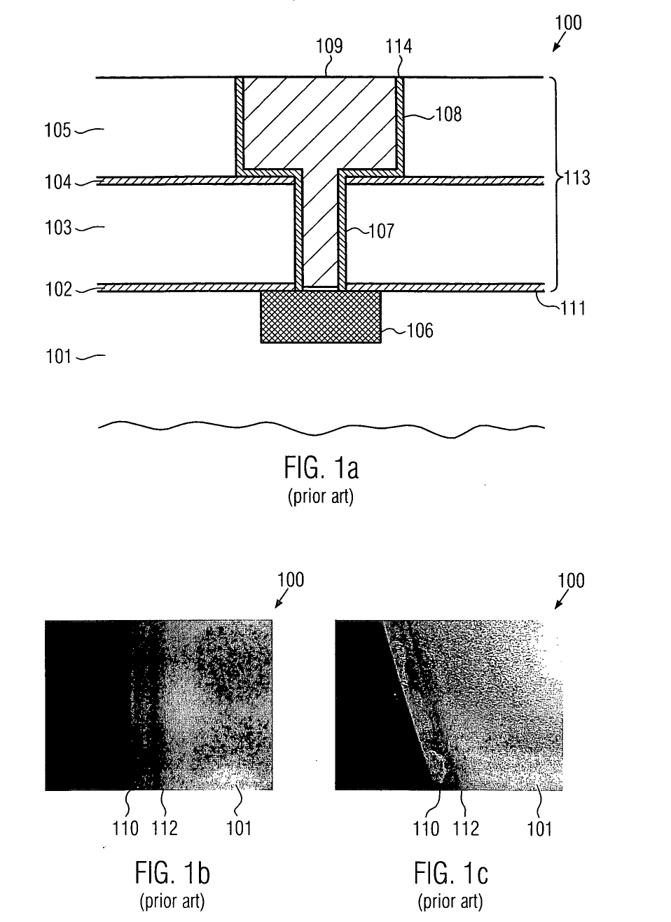

FIG. 1b shows an image of the semiconductor structure 100, a schematic cross-sectional view of which is depicted in FIG. 1a, in a stage of the manufacturing process after the formation of the contact via 107. On a second surface 112 of the substrate 101, a contamination layer 110 has been formed. The second surface 112 is located on a backside of the substrate 101, opposite to the front side on which the interlayer dielectric stack 113 and the circuit element 106 are formed.

The etch gas used in the dry etching process employed in the formation of the contact via 107 comprises carbon fluorides such as carbon tetrafluoride (CF₄). In the glow discharge, fluorine is separated from the carbon fluoride molecules, and the residues of the molecules react with other carbon fluoride molecules. Thus, higher order carbon fluorides are created. The higher order carbon fluorides may undergo further chemical reactions. In these chemical reactions, carbon fluoride polymers are created.

The polymers are deposited on cold sites in the etch chamber where the dry etching process is performed. In particular, the polymers are deposited on the first surface 111 and the second surface 112 of the substrate 101. In the dry etching process, however, the first surface 111 is exposed to an ion bombardment. Therefore, the polymers are quickly removed from the first surface 111. The second surface 112 of the substrate 101 is affected by the ions to a lesser extent. Hence, polymers may remain on the second surface 112 of the substrate 101 and form a contamination layer 110 thereon. Depending on the etch time, which is particularly long in the formation of the via 107 extending through the whole interlayer dielectric stack 113, the contamination layer 110 may have a thickness of up to several hundred Angstrom. A further deposition of polymers on the second surface 112 of the substrate 101 may occur in the formation of the trench 108. Thus, the thickness of the contamination layer 110 may be further increased.

The adhesion between the substrate 101 and the contamination layer 110 is relatively low. FIG. 1c shows an image of the semiconductor structure 100 in a later stage of the manufacturing process, after the deposition of the barrier layer 108. It can be seen that, due to the relatively low adhesion between the contamination layer 110 and the substrate 101, polymer flakes have split off from the contamination layer 110.

These polymer flakes may be responsible for the contamination of the semiconductor structure 100 and tools in later stages of the manufacturing process which can adversely affect the product yield of the process.

The present invention is generally directed to methods of forming a semiconductor structure wherein a contamination layer formed in a dry etching process which is performed in the formation of at least one recess in a layer of a material provided on a first surface of a substrate is removed from a second surface of the substrate. The first surface may be located on a front side of the substrate where circuit elements are formed. The second surface can be located on a backside and/or a bevel of the substrate. Due to the removal of the contamination layer, a splitting off of polymer flakes and contaminations created by the polymer flakes can advantageously be avoided. This contamination layer 110 may be formed during any or all of the anisotropic dry etching processes discussed previously.

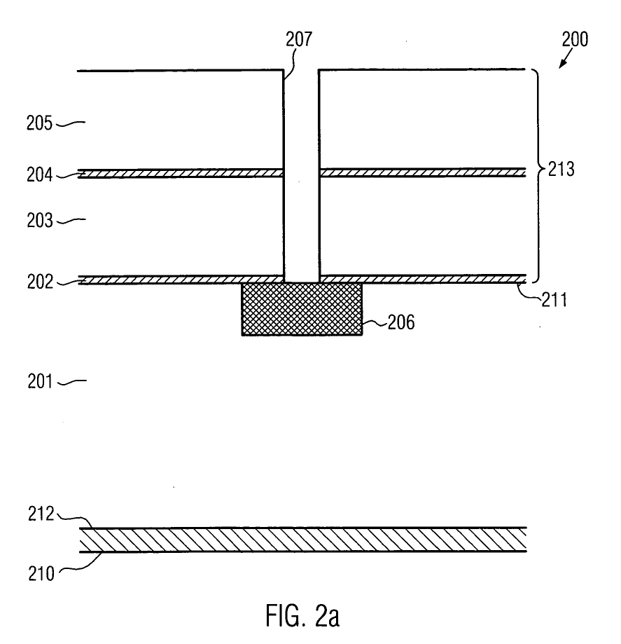

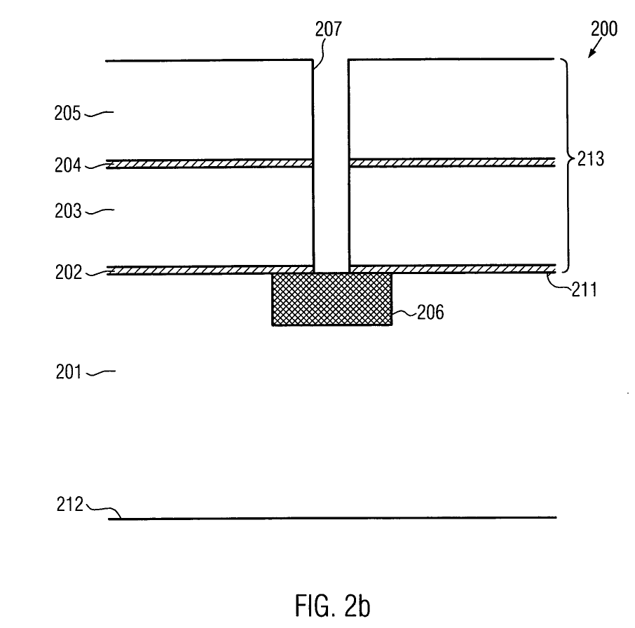

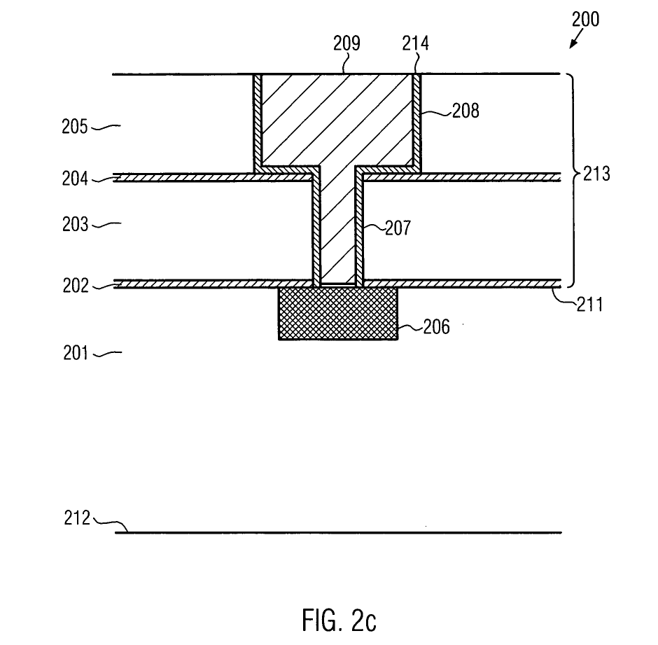

Further embodiments of the present invention will now be described with reference to FIGS. 2a-2c. FIG. 2a shows a schematic cross-sectional view of a semiconductor structure 200 in a first stage of a manufacturing process according to the present invention. The semiconductor structure 200 comprises a substrate 201. The substrate 201 has a first surface 211 and a second surface 212. An electrical element 206 which may comprise an electrically conductive line is located below the first surface 211. The second surface 212 may at least partially be located on a side of the substrate 201 opposite the first surface 211.

In one embodiment of the present invention, the substrate 201 comprises a semiconductor wafer. On a front side of the semiconductor wafer, the electrical element 206 and, optionally, a plurality of other electrical elements are formed. The second surface 212 is at least partially located over the backside of the semiconductor wafer. Additionally, the second surface 212 may comprise portions located over a bevel at the edge of the semiconductor wafer.

On the first surface 211 of the substrate 201, an interlayer dielectric stack 213 is formed. The interlayer dielectric stack 213 can comprise a first etch stop layer 202, a first layer 203 of an interlayer dielectric, a second etch stop layer 204 and a second layer 205 of an interlayer dielectric. The layers 202, 203, 204 and 205 of the interlayer dielectric stack 213 may be formed by means of methods known to skilled persons such as, e.g., plasma enhanced chemical vapor deposition, chemical vapor deposition and/or spin coating.

In one illustrative embodiment, the first layer 203 of interlayer dielectric and/or the second layer 205 of interlayer dielectric may comprise a material having a relative permittivity of about 3.1 or less. In particular embodiments, the layers 203, 205 may comprise hydrogenated silicon oxycarbide (SiCOH) or hydrogenated silsesquioxane. Advantageously, a comparatively low relative permittivity of the layers 203, 205 of interlayer dielectric reduces signal propagation delays in electrically conductive lines to be formed in the interlayer dielectric stack 213. The first etch stop layer 202 and the second etch stop layer 204 may comprise a material having a moderately lower etch rate when exposed to an etch chemistry adapted to etch the material of the layers 203, 205, for example silicon carbide (SiC).

The present invention, however, is not limited to embodiments wherein interlayer dielectrics having a low relative permittivity are employed. In other embodiments of the present invention, the layers 203, 205 may comprise silicon dioxide, whereas the etch stop layers 202, 204 comprise silicon nitride. Alternatively, the layers 203, 205 may comprise silicon nitride, whereas the etch stop layers 202, 204 comprise silicon dioxide.

A contact via 207 is formed in the interlayer dielectric stack 213 over the electrical element 206. Similar to the damascene process according to the state of the art described above with reference to FIGS. 1a-1c, this can be done by forming a first mask (not shown) exposing those portions of the interlayer dielectric stack wherein the via 207 is to be formed, and then performing a dry etching process. In addition to the contact via 207, a plurality of further contact vias (not shown) may be formed in the process steps applied for the formation of the contact via 207.

In the dry etching process, a gaseous etchant comprising carbon fluorides, for example a composition comprising carbon tetrafluoride (CF₄), may be used. A reactive species is created from the etchant by means of a glow discharge in an etch chamber wherein the etchant is provided. The semiconductor structure 200 may be cooled in the dry etching process. In the glow discharge, chemical reactions creating by-products which can condense on the semiconductor structure 200 may occur. In some embodiments of the present invention, polymers, for example carbon fluoride polymers, may be created from carbon fluorides present in the etchant, similar to the method according to the state of the art described above. The present invention, however, is not limited to embodiments wherein the etchant used comprises carbon fluorides. Instead, embodiments of the present invention may be applied whenever an etching process creates by-products which may condense on the semiconductor structure to be etched.

The by-products are deposited on the semiconductor structure 200. In the etching process, ions impinge on the first surface 211. Due to the ion bombardment, by-products deposited on the first surface 211 are quickly removed. However, on the second surface 212, to the contrary, the by-products create a contamination layer 210 similar to the contamination layer 110 formed in the method according to the state of the art described above with reference to FIGS. 1a-1c. After the etching process, the first mask is removed.

A further stage of the damascene process is shown in FIG. 2b. In accordance with one aspect of the present invention, the contamination layer 210 is removed from the second surface 212 of the substrate 201. In one embodiment of the present invention, this can be done by at least partially inserting the semiconductor structure 200 into a cleaning solution. The cleaning solution may comprise chemicals adapted to solve and/or decompose the by-products, leaving the materials of the substrate 201 substantially intact. In illustrative embodiments of the present invention wherein the contamination layer 210 comprises a polymer, e.g., a carbon fluoride polymer, the cleaning solution can comprise ACT970 available from Zeon Chemicals L.P (Louisville, Ky.) or other wet clean chemistries adapted to remove polymers.

In some embodiments of the present invention, wherein the first surface 211 is located over a front side of a semiconductor wafer and the second surface 212 is located over a backside of a semiconductor wafer, only the second surface 212 may be inserted into the cleaning solution. To this end, the semiconductor structure 200 may be moved towards a surface of the cleaning solution, the backside of the semiconductor wafer being directed towards the cleaning solution. The motion of the semiconductor structure 200 can be stopped as soon as the semiconductor structure 200 touches the surface of the cleaning solution, which may be detected, e.g., optically or from an increase of the level of the cleaning solution. Thus, the first surface of the semiconductor structure 200 where the contact via 207 and the electrical element 206 are located is not exposed to the cleaning solution. Hence, potential adverse effects resulting from a contact between the cleaning solution and the electrical element 206 may advantageously be avoided.

In other embodiments of the present invention, the semiconductor structure 200 may totally be inserted into the cleaning solution. In still further embodiments of the present invention, the cleaning solution may be sprayed onto the second surface of the semiconductor structure 200. Spraying may be performed in a batch process, wherein a plurality of semiconductor structures which includes the semiconductor structure 200 is enclosed in a chamber and the cleaning solution is sprayed onto all the semiconductor structures simultaneously. In other embodiments of the present invention, the semiconductor structure 200 may individually be sprayed with the cleaning solution.

Advantageously, in spraying the cleaning solution onto the semiconductor structure 200, smaller amounts of the cleaning solution may be required than in inserting the semiconductor structure 200 into the cleaning solution. Additionally, spraying the cleaning solution onto the semiconductor structure 200 allows continually exposing the second surface 212 to fresh cleaning solution and thus improves the controllability of the process.

Due to the removal of the contamination layer 210, substantially no polymer flakes stemming from the previous etch processes are split off from the semiconductor structure 200 in later stages of the manufacturing process. Hence, a contamination of the semiconductor structure 200 and tools can be significantly reduced compared to the method according to the state of the art described above and a yield of the manufacturing process can advantageously be increased.

A further stage of the manufacturing process is shown in FIG. 2c. A trench 208 is formed in the second layer 205 of interlayer dielectric. Similar to the formation of the trench 108 in the method according to the state of the art described above with reference to FIGS. 1a-1c, this can be done by depositing a second mask of photoresist exposing those portions of the second layer 205 wherein the trench 208 is to be formed over the first surface 211 of the substrate 201 and performing a dry etching process. The second etch stop layer 204 may protect the first layer 203 of interlayer dielectric from being affected by the etchant or can provide an indication when the etch front has passed the second layer 205 of interlayer dielectric. In other embodiments of the present invention, the etch process can be performed without providing the etch stop layer 204. A portion of photoresist can be located inside the contact via 207, protecting the electrical element 206 from being affected by the etchant. In addition to the trench 208, one or more further trenches may be formed simultaneously by providing further portions of the second layer 205 of interlayer dielectric which are not covered by the second mask.

Similar to the dry etching performed in the formation of the contact via 207, in the dry etching performed in the formation of the trench 208, a by-product of chemical reactions occurring in the plasma, for example a polymer which may comprise a carbon fluoride polymer, can be deposited on the semiconductor structure 200 and form a contamination layer (not shown) similar to the contamination layer 210 on the second surface 212 of the substrate 201.

This contamination layer can be removed, e.g., by at least partially inserting the semiconductor structure 200 into a cleaning solution or spraying a cleaning solution on the second surface 212, as described above. Thus, advantageously, a splitting off of polymer flakes in subsequent steps of the manufacturing process and a contamination of the semiconductor structure 200 and tools, as well as a reduction of product yield resulting therefrom, may be significantly reduced.

After the formation of the trench, a diffusion barrier layer 214 and a metal layer can be deposited, and a chemical mechanical polishing process may be performed in order to remove portions of the diffusion barrier layer 214 and the metal layer 209 outside the via 207 and the trench 208. Thus, a metal interconnection 209 can be formed.

The present invention is not restricted to embodiments wherein first at least one via is formed, and then at least one trench is formed, as described above. In other embodiments of the present invention, first at least one trench is formed in the second layer 205 of interlayer dielectric. The formation of the at least one trench comprises a dry etching process. In the dry etching process, a contamination layer similar to the contamination layer 210 is formed on the second surface 212 of the semiconductor substrate 201. The contamination layer is removed, as described above. Then, at least one contact via is formed at a bottom of the at least one trench, which may be done by means of a dry etching process. Thereafter, a further contamination layer may be removed from the second surface 212 of the substrate 201.

The removal of the contamination layer need not be performed twice, as in the embodiments described above. In further embodiments of the present invention, only one removal of a contamination layer may be performed. This can be done after the formation of the at least one contact via, or after the formation of the trench.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method of forming a semiconductor structure, comprising:
providing a substrate comprising a layer of a material formed on a first surface of said substrate;
performing at least one dry etching process to form at least one recess in said layer of material; and
removing a contamination layer formed in said dry etching process from a second surface of said substrate.

2. The method of claim 1, wherein said second surface is at least partially located on a side of said substrate opposite said first surface.

3. The method of claim 2, wherein said substrate comprises at least one electrical element located below said first surface.

4. The method of claim 1, wherein said substrate comprises a semiconductor wafer having a front side and a backside, at least one electrical element is formed over said front side, said first surface is located over said front side, and said second surface is located over said backside.

5. The method of claim 4, wherein a portion of said second surface is located over a bevel of said semiconductor wafer.

6. The method of claim 1, wherein said at least one recess comprises a contact via.

7. The method of claim 6, further comprising forming at least one trench, said formation of said at least one trench being performed after said removal of said contamination layer.

8. The method of claim 1, wherein said at least one recess comprises a trench.

9. The method of claim 8, further comprising forming at least one contact via, said formation of said at least one contact via being performed after said removal of said contamination layer.

10. The method of claim 1, wherein said layer of material comprises an interlayer dielectric.

11. The method of claim 10, wherein said interlayer dielectric has a relative permittivity of about 3.1 or less.

12. The method of claim 1, wherein said contamination layer comprises a polymer.

13. The method of claim 12, wherein said polymer comprises carbon and fluorine.

14. The method of claim 1, wherein said removal of said contamination layer comprises at least partially inserting said semiconductor structure into a cleaning solution.

15. The method of claim 1, wherein said removal of said contamination layer comprises spraying a cleaning solution onto said second surface.

16. A method of forming a semiconductor structure, comprising:
providing a substrate comprising a layer of an interlayer dielectric formed over a front side of said substrate;
performing at least one dry etching process to form at least one recess in said layer of interlayer dielectric; and
removing a polymer layer formed during said at least one dry etching process from a backside of said substrate.

17. The method of claim 16, wherein said at least one recess comprises at least one contact via.

18. The method of claim 17, further comprising forming at least one trench, said formation of said at least one trench being performed after said removal of said polymer layer.

19. The method of claim 16, wherein said at least one recess comprises at least one trench.

20. The method of claim 19, further comprising forming at least one contact via, said formation of said at least one contact via being performed after said removal of said polymer layer.

21. The method of claim 16, wherein said interlayer dielectric has a relative permittivity of about 3.1 or less.

22. The method of claim 16, wherein said polymer comprises carbon and fluorine.

23. The method of claim 16, wherein said removal of said polymer layer comprises at least partially inserting said semiconductor structure into a cleaning solution.

24. The method of claim 16, wherein said removal of said polymer layer comprises spraying a cleaning solution on said backside of said substrate.
